(19) United States
(12) Patent Application Publication
(10) Pub. No.: US 2011/0182013 A1
(43) Pub. Date: Jul. 28, 2011

(54) Frame Case for Portable Electronic Devices

(75) Inventors: Sean Savitt, Hollywood, FL (US); Edward Martin, Hollywood, FL (US); Christopher Piedra, Hollywood, FL (US); Chanseol Chung, Hollywood, FL (US); Robert Crawford, Hollywood, FL (US)

(73) Assignee: MARWARE, INC., Hollywood, FL (US)

(21) Appl. No.: 13/016,008

(22) Filed: Jan. 28, 2011

Related U.S. Application Data
(60) Provisional application No. 61/299,144, filed on Jan. 28, 2010.

(51) Int. Cl. H05K 5/00

(52) U.S. Cl. 361/679.01

(57) ABSTRACT

A frame case includes a device case for holding a portable electronic device having a display to be viewed by a user; and a frame associated with the device case for holding a photograph or graphics to be viewed by the user.

### CROSS-REFERENCE TO RELATED APPLICATION

This application claims the priority, under 35 U.S.C. §119(e), of provisional application No. 61/299,144 filed Jan. 28, 2010; the prior application is herewith incorporated by reference in its entirety.

### BACKGROUND OF THE INVENTION

1. Field of the Invention

The invention relates to a frame case for portable electronic devices, such as mobile phones, portable media players and handheld game consoles.

2. Description of the Related Art

Prior art cases for portable or handheld electronic devices are used to protect the device against damage which may be caused by dropping the device or inadvertently bringing it into contact with other objects. However, such cases cannot be personalized, such as by adding a photograph of the user's choice and therefore the user of such device often carries separate photographs, perhaps in a separate case which is provided for that purpose.

### BRIEF SUMMARY OF THE INVENTION

It is accordingly an object of the invention to provide a frame case for portable electronic devices, which overcomes the above-mentioned disadvantages of the heretofore-known devices and methods of this general type and which permits the user to attach a photograph to the device through the use of the case.

With the foregoing and other objects in view there is provided, in accordance with the invention, a frame case, comprising a device case for holding a portable electronic device having a display to be viewed by a user, and a frame associated with the device case for holding a photograph or graphics to be viewed by the user.

In accordance with another feature of the invention, the display and the photograph or graphics are to be viewed by the user at different locations of the frame case, for example opposite one another.

In accordance with a further feature of the invention, the frame is a cutout in said device case through which the user can view the photograph or graphics.

In accordance with an added feature of the invention, a transparent, preferably plastic, sheet is disposed between the photograph or graphics and said frame.

Other features which are considered as characteristic for the invention are set forth in the appended claims.

Although the invention is illustrated and described herein as embodied in a frame case for portable electronic devices, it is nevertheless not intended to be limited to the details shown, since various modifications and structural changes may be made therein without departing from the spirit of the invention and within the scope and range of equivalents of the claims.

The construction of the invention, however, together with additional objects and advantages thereof will be best understood from the following description of the specific embodiments when read in connection with the accompanying drawings.

### BRIEF DESCRIPTION OF THE SEVERAL VIEWS OF THE DRAWING

FIG. 1 is a diagrammatic, perspective view of a frame case for portable electronic devices according to the invention, in which a photograph has been inserted;

FIG. 2 is a perspective view of the frame case, in which graphics have been inserted;

FIG. 3 is an exploded, perspective view of parts of the frame case; and

FIG. 4 is a perspective view illustrating photographs to be exchanged in the frame case.

### DETAILED DESCRIPTION OF THE INVENTION

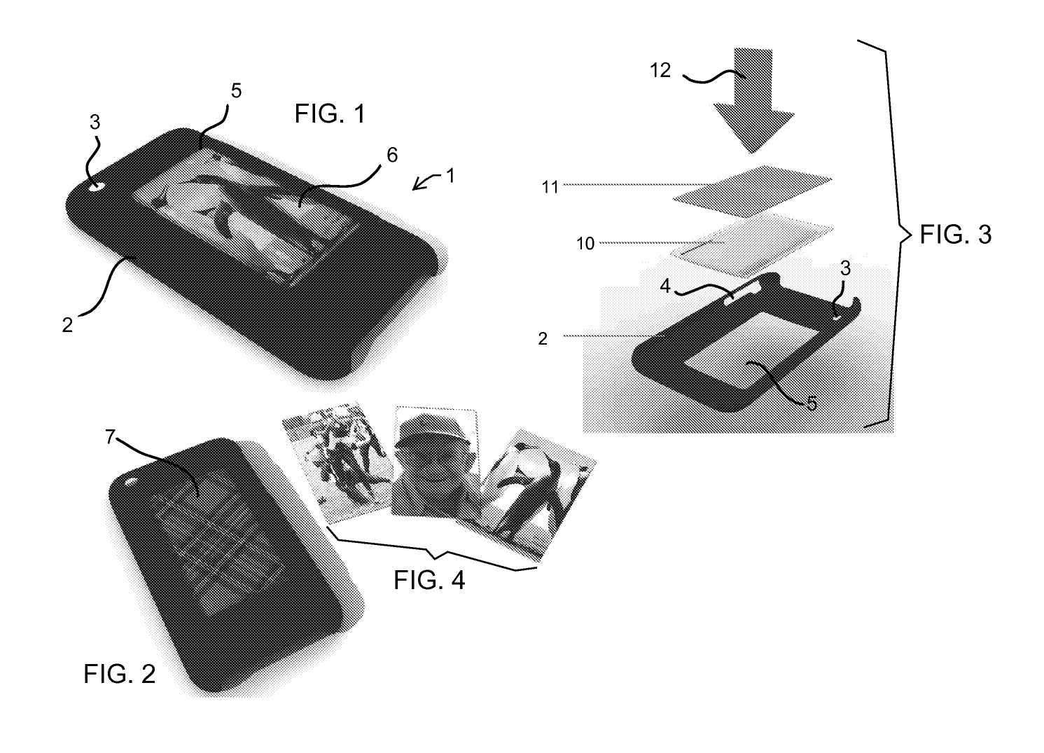

Referring now to the figures of the drawing in detail and first, particularly, to FIG. 1 thereof, there is seen a frame case 1 according to the invention, having a portable device case 2 for holding a portable electronic device, such as a mobile phone, a portable media player or a handheld game console. Openings 3, 4 having different shapes for accessing switches, buttons or jacks of the device are provided in the device case 2. The device case 2 includes a picture or graphics frame 5 in the form of a cutout or window in the device case 2. In FIG. 1, a photograph 6 is disposed in and is displayed by the frame 5. FIG. 2 shows the frame case 1 with graphics 7 displayed instead. The front of the portable electronic device carrying its display, faces away from the frame 5. The sides of the device case 2 grip the portable electronic device to hold it in place.

The frame case 1 is shown in the exploded view of FIG. 3 to be assembled from the device case 2, a clear plastic sheet 10 and a piece of photographic paper or a substrate 11 on which the photograph 6 or graphics 7 are superimposed. An arrow 12 indicates the direction of assembly of the parts 2, 10, 11. The clear plastic sheet 10 holds the piece of photographic paper or substrate 11 in place in such a way that a user of the device can view it.

FIG. 4 illustrates that different photographs or images are exchangeable within the frame 5.

1. A frame case, comprising:
a device case for holding a portable electronic device having a display to be viewed by a user; and
a frame associated with said device case for holding a photograph or graphics to be viewed by the user.

2. The frame case according to claim 1, wherein the display and the photograph or graphics are to be viewed by the user at different locations of the frame case.

3. The frame case according to claim 1, wherein said frame is a cutout in said device case through which the user can view the photograph or graphics.

4. The frame case according to claim 1, which further comprises a transparent sheet disposed between the photograph or graphics and said frame.
